(19) United States
(12) Patent Application Publication
(10) Pub. No.: US 2008/0047605 A1
(43) Pub. Date: Feb. 28, 2008

(54) MULTI-JUNCTION SOLAR CELLS WITH A HOMOGENIZER SYSTEM AND COUPLED NON-IMAGING LIGHT CONCENTRATOR

(75) Inventors: Pablo Benitez, Madrid (ES); Roland Winston, Merced, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Regents of the University of California, Oakland, CA (US)

(21) Appl. No.: 11/683,934

(22) Filed: Mar. 8, 2007

Related U.S. Application Data
(63) Continuation-in-part of application No. PCT/US06/29464, filed on Jul. 28, 2006.
(60) Provisional application No. 60/703,667, filed on Jul. 28, 2005.
(60) Provisional application No. 60/776,596, filed on Feb. 24, 2006.
(60) Provisional application No. 60/780,520, filed on Mar. 8, 2006.

(30) Foreign Application Priority Data
Jul. 28, 2006 (US) PCT/US06/29464

(51) Int. Cl. H01L 31/042; G02B 5/09

(52) U.S. Cl. 136/259; 359/853

(57) ABSTRACT

Optical systems and methods that concentrate light from a distant source, such as the sun, onto a target device, such as a solar cell. Light impinging from the distant source, is focused or imaged by a plurality of primary reflective segments of a primary mirror element onto a plurality of corresponding secondary reflective segments. The secondary mirror segments image the corresponding primary segments onto an exit aperture such that the exit aperture is uniformly illuminated. A target cell may be located proximal to the exit aperture, or an entry aperture of a non-imaging concentrator may be positioned proximal the exit aperture, wherein the concentrator concentrates the reflected light onto the target cell.

### CROSS-REFERENCES TO RELATED APPLICATIONS

This application is a continuation-in-part application of PCT application PCT/US2006/029464, filed Jul. 28, 2006, which claims the benefit of U.S. Provisional Application Ser. No. 60/703,667, filed Jul. 28, 2005 and U.S. Provisional Application Ser. No. 60/776,596, filed Feb. 24, 2006, the disclosures of which are incorporated herein by reference in their entirety. This application also claims the benefit of U.S. Provisional Application Ser. No. 60/780,520 (Attorney Docket No.18062A-009600US), filed Mar. 8, 2006, the disclosure of which is incorporated herein by reference in its entirety.

### BACKGROUND OF THE INVENTION

The present invention relates generally to optical concentrator systems and methods utilizing solar cells for collecting the concentrated light energy, and more particularly to optical concentrator systems and methods incorporating homogenizer elements.

Solar cells for electrical energy production are very well known but have limited utility due to the very high cost of production. For example, although substantial research has been ongoing for many years, the cost per Killowatt-hour (Kwh) still is about ten times that of conventional electric power production. To compete with wind power or other alternative energy sources, the efficiency of production of electricity from solar cells should be drastically improved.

One prior system described in US Patent Application publication 2006-0207650-A1, titled “Multi-Junction Solar Cells with an Aplanatic Imaging System and Coupled Non-Imaging Light Concentrator,” which is hereby incorporated by reference in its entirety, considers a two mirror aplanatic system (which produce sharp imaging of normal incidence rays on the cell center and satisfies the Abe sine condition) which may be combined with a non-imaging concentrator. FIG. 1 shows such a two-mirror aplanatic system without a non-imaging concentrator. Primary mirror 10 concentrates the light onto the secondary mirror 11, which illuminates the target solar cell 12. That system has a clear limitation because it produces a highly non-uniform illumination on the solar cell, which reduces the cell efficiency and system reliability. This is because the optics is imaging the plane at infinity onto the plane of the target, where the cell is placed, and thus the sun is imaged on the cell. The angular acceptance of the two mirror aplanatic concentrator is several times (for instance, 3) greater than the angular size of the sun to allow for tolerances. The imaging mapping makes the acceptance angle-to-sun angle ratio the same as the cell diameter-to-sun image diameter ratio. Therefore, the area of the round target would be 32 times greater than the sun image area. If the average concentration of the prior art design is 500 suns, the local concentration can reach as much as 3²×500=4,500 suns. This value cannot be tolerated by the present high-efficiency multi-junction cells, which show an abrupt drop in efficiency if they operate above 2,000-3,000 suns.

Other related prior art is disclosed in a paper by L. W. James, “Use of Imaging Refractive Secondaries in Photovoltaic Concentrators”, SAND89-7029, Alburquerque, N.Mex., 1989. In that paper, and as shown in FIG. 2, a Kohler integrator system is used as a photovoltaic concentrator. The Kohler integrator consists of two imaging optical elements (primary and secondary) with positive focal length (i.e., producing a real image of an object at infinity). The secondary is placed at the focal plane of the primary, and the secondary images the primary on the cell. In James' paper, the photovoltaic Kohler concentrator is composed by a Fresnel lens 20 as primary and a single-surface imaging lens 21 as secondary that encapsulates the cell 22, as illustrated in FIG. 2. The primary images the sun on the secondary aperture 23. As the primary is uniformly illuminated by the sun, the irradiance distribution on the cell is also uniform, and it will remain unchanged when the sun moves within the acceptance angle (equivalently when the sun image 24 moves within the secondary aperture). The concentration-acceptance angle product that can be attained with this configuration is very limited, because numerical aperture on the cell is small. Additionally, the system is necessarily not compact because the optics used are refractive and includes a single Kohler integration element.

Therefore it is desirable to provide optical concentrator systems and methods that overcome the above and other problems.

### BRIEF SUMMARY OF THE INVENTION

The present invention provides systems and methods for concentrating light from a distant source, such as the sun, onto a target device, such as a solar cell. Light impinging from the distant source, is focused or imaged by a plurality of radially symmetric primary reflective segments of a primary mirror element onto a plurality of corresponding radially symmetric secondary reflective segments. The secondary mirror segments image the corresponding primary segments onto an exit aperture such that the exit aperture is uniformly illuminated. A target cell may be located proximal to the exit aperture, or an entry aperture of a non-imaging concentrator may be positioned proximal the exit aperture, wherein the concentrator concentrates the reflected light onto the target cell.

Aspects of the present invention are directed to optical devices and systems that provide extremely high solar flux onto a multi-junction solar cell, or other target cell, to produce efficient electrical output. An aplanatic optical imaging system, according to certain aspects, includes a Kohler homogenizer primary and secondary mirror subsystem that directs and concentrates illumination to a solar cell positioned proximal an exit aperture such that uniform irradiance conditions are achieved for high intensity light concentration onto the solar cell. As used herein, “aplanatic” generally refers to the condition of freedom from spherical aberration and coma. Thus, as used herein, “aplanatic optics” or “aplanatic optical system” or similar phrases generally refer to optical elements or systems that correct for, or are substantially free from, spherical aberration or coma. In certain aspects, a non-imaging light concentrator, or flux booster, is efficiently coupled to the primary and secondary mirrors.

A variety of Kohler homogenizer and planar optical systems formed by two mirrors can provide the necessary components to deliver light to a multi-junction solar cell or other solar cell. In one embodiment, radial symmetric mirror segments on both primary and secondary mirrors are pair-wise correlated so that a segment on the primary images the field of view onto the corresponding secondary segment, while the secondary segment in turn, images the primary segment on the target. In one embodiment, a secondary mirror is co-planar with the entrance aperture, and the exit aperture is co-planar with the vertex of the primary mirror. In another embodiment, the inter-mirror space is filled with a dielectric with index of refraction, n, such that the numerical aperture (“NA”) is increased by a factor of n. In another embodiment, a non-imaging light concentrator is disposed at the exit aperture of the primary mirror. In one aspect, the non-imaging concentrator is a θ₁/θ₂ concentrator with θ₁ chosen to match the NA of the two-mirror system (sin θ₁=NA/n) while θ₂ is chosen to satisfy a subsidiary condition, such as maintaining total internal reflection (“TIR”) or limiting the angle of irradiance on the multi-junction solar cell. In another aspect, the non-imaging concentrator is a flow line concentrator or a tailored non-imaging concentrator.

According to one aspect of the present invention, an optical device is provided that typically comprises an aplanatic optical imaging system including a segmented primary reflective element defining an entrance aperture and having a plurality of aspherical primary reflective segments, and a segmented secondary reflective element having a plurality of aspherical secondary reflective segments. The primary and secondary reflective segments are pair-wise correlated so that a primary reflective segment images a field of view onto a corresponding secondary reflective segment, and the secondary reflective segment images the corresponding primary segment onto an exit aperture. In certain aspects, the device typically includes a target element positioned proximal to a vertex of the primary reflective element. One type of target element is a solar cell. In certain aspects, the primary reflective segments have a substantially parabolic reflecting surface and the secondary reflective segments have a substantially elliptical reflecting surface. In certain aspects, the primary reflective segments forming the primary reflective element include slope discontinuities where they meet such that the second derivative of the primary reflective element surface is discontinuous, and the secondary reflective segments forming the secondary reflective element include slope discontinuities where they meet such that the second derivative of the secondary reflective element surface is discontinuous.

According to another aspect of the present invention, an optical device is provided that typically includes an aplanatic optical imaging system that includes a segmented primary reflective element defining an entrance aperture and having a plurality of primary reflective segments, and a segmented secondary reflective element having a plurality of secondary reflective segments. The device also typically includes a target element positioned proximal to an exit aperture. The primary and secondary reflective segments are pair-wise correlated so that light impinging on a primary reflective segment is focused onto a corresponding secondary reflective segment, and the secondary reflective segment images the corresponding primary segment onto the exit aperture such that the target element is substantially uniformly illuminated. In certain aspects, the primary reflective segments and the secondary reflective segments are aspherical. In certain aspects, the target element includes a solar cell. In certain aspects, the device further includes a non-imaging concentrator having an entrance aperture disposed proximal to the exit aperture. In certain aspects, the primary reflective segments forming the primary reflective element include slope discontinuities where they meet such that the second derivative of the primary reflective element surface is discontinuous, and the secondary reflective segments forming the secondary reflective element include slope discontinuities where they meet such that the second derivative of the secondary reflective element surface is discontinuous.

According to yet another aspect of the present invention, a method is provided for concentrating light onto a solar cell. The method typically includes positioning an aplanatic optical imaging device to receive incident light from a light source, where the device typically includes a segmented primary reflective element having a plurality of primary reflective segments, and a segmented secondary reflective element having a plurality of corresponding secondary reflective segments. The method also typically includes reflecting incident light by the primary mirror segment s onto corresponding secondary mirror segments, and reflecting the reflected light by the secondary mirror segments onto a target cell, wherein the target cell is substantially uniformly illuminated by the incident light. In certain aspects, the device further includes a non-imaging concentrator position proximal to the target cell, and the method further typically includes concentrating the incident light reflected by the secondary mirror segments onto the target cell. In certain aspects, the light source is the sun, and the method further typically includes repositioning the device so as to track the motion of the sun such that incident light from the sun is received within an acceptance angle of the device.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE DRAWINGS

FIG. 1 illustrates a solid-dielectric aplanatic two mirror design disclosed in prior art;

FIG. 2 illustrates a photovoltaic Kohler concentrator disclosed in prior art;

FIG. 3 illustrates a solid dielectric two-mirror Kohler radial homogenizer optical system according to one embodiment;

FIG. 4 illustrates a 3-dimensional (3D) view of the two-mirror Kohler radial homogenizer optical system of FIG. 3;

FIG. 5 illustrates the operation of a two-mirror Kohler radial homogenizer optical system when the sun is off-center but still within the design acceptance angle according to one embodiment;

FIG. 6 illustrates a non-imaging concentrator added to the two-mirror Kohler radial homogenizer optical system to increase the concentration ratio of the acceptance angle according to one embodiment;

FIG. 7 illustrates a two-mirror Kohler radial homogenizer optical system that includes volumes of different refractive indices according to one embodiment;

FIG. 8 illustrates a Kohler homogenizer optical system that includes volumes of different refractive indices, and where Kohler homogenization is performed between the two surfaces of the front top dielectric cover according to one embodiment;

FIG. 9 illustrates a Kohler radial homogenizer optical system that includes volumes of different refractive indices, and where Kohler radial homogenization is performed between the entry surface and the primary mirror according to one embodiment;

FIG. 10 illustrates a Kohler radial homogenizer optical system that includes volumes of different refractive indices, and where Kohler radial homogenization is performed between the entry surface and the secondary mirror according to one embodiment;

FIG. 11 illustrates a Kohler radial homogenizer optical system that includes volumes of different refractive indices, and where Kohler radial homogenization is performed between the entry surface and the exit surface according to one embodiment;

FIG. 12 illustrates a Kohler radial homogenizer optical system that includes volumes of different refractive indices, and where Kohler radial homogenization is performed between the inner surface of the top cover and the primary mirror according to one embodiment;

FIG. 13 illustrates a Kohler radial homogenizer optical system that includes volumes of different refractive indices, and where Kohler radial homogenization is performed between the inner surface of the top cover and the secondary mirror according to one embodiment;

FIG. 14 illustrates a Kohler radial homogenizer optical system that includes volumes of different refractive indices, and where Kohler radial homogenization is performed between the inner surface of the top cover and the exit surface according to one embodiment;

FIG. 15 illustrates a Kohler radial homogenizer optical system that includes volumes of different refractive indices, and where Kohler radial homogenization is performed between the primary mirror and the exit surface according to one embodiment;

FIG. 16 illustrates a Kohler radial homogenizer optical system that includes volumes of different refractive indices, and where Kohler radial homogenization is performed between the secondary mirror and the exit surface according to one embodiment; and

FIGS. 17A and 17B illustrate the shaping of the exit surface to improve the uniformity of the system when the sun is on axis according to one embodiment.

FIG. 18a illustrates a perspective view of a specific optical system having segmented primary and secondary mirror segments. FIG. 18b shows an example of relative angular transmission as a function of incidence angle for the system of FIG. 18a. FIG. 18c illustrates a plurality of systems mounted on multiple heat sinks.

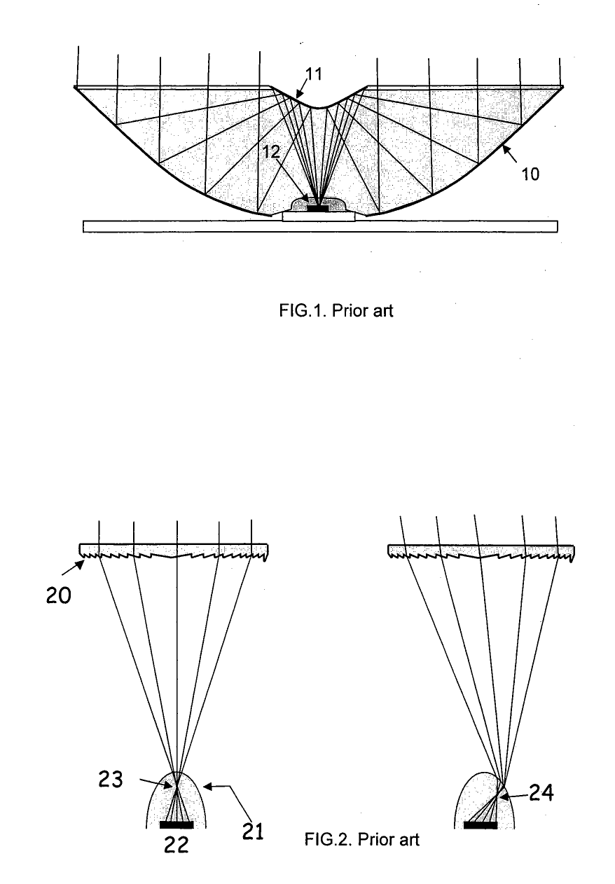

### DETAILED DESCRIPTION OF THE INVENTION

The present invention provides optical imaging systems and methods using homogenizers to concentrate and uniformly irradiate a target cell.

Aspects of the present invention make use of the inventions, including embodiments and design methods, described in U.S. Provisional Application No. 60/703,667 titled “Free-Form Lenticular Optical Elements and their Application to Condensers and Headlamps”, filed Jul. 28, 2005, which is incorporated herein by reference in its entirety.

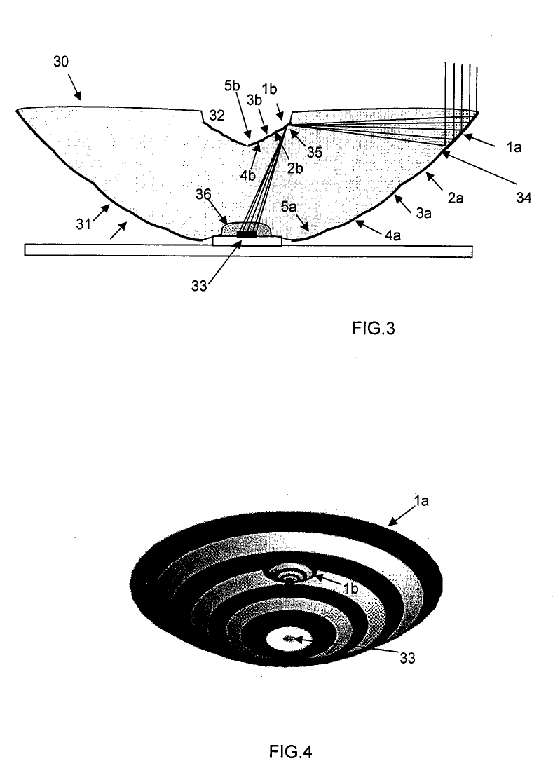

An optical system constructed in accordance with one embodiment of the invention is shown in FIG. 3. As shown, in one embodiment, a segmented secondary mirror 32 is substantially co-planar with the entrance aperture 30 of a primary mirror 31. The entrance aperture 30 and the exit aperture 36 are substantially flat. The segments on the primary 1a, 2a, etc. are essentially parabolic, with the focus of each at the associated mirror segment 1b, 2b, etc. on the secondary and vertical axis. The secondary mirror segments 1b, 2b, etc. are essentially elliptic with foci at the locations of the associated primary mirror segment and the target 33. There is continuity in profile but discontinuity in slope in both the secondary and primary mirrors. The target plane of the combination of the primary mirror 31 and the secondary mirror 32 resides at the target 33. In one aspect, the target 33 includes a solar cell. The optical system as shown in FIG. 3 operates to receive and radially integrate incoming light from a distant source, e.g., the sun, and concentrate the light onto the target 33. However, a target 22 may include a light source or an illumination element, in which case the optical system performs high collimation and radial integration of outgoing light. This reversibility applies to all embodiments disclosed herein.

In this embodiment, the edges of a given segment of the secondary mirror are designed so that their images at infinity through the associated primary segment match the design acceptance angle. On the other hand, the edges of a given segment of the primary are designed so that their images on the target through the associated secondary segment match the target size, e.g., cell size. Because the segments on the primary are uniformly illuminated, the illumination on the cell is also uniform in two dimensions.

The mirror segments can also be configured to optimize the global performance. For instance, the focus position of the parabola or ellipses, and the parabola axis could be considered a parameter, and a multi-parameter optimization program can be used to optimize the acceptance angle of the entire system. Alternatively, the parabola axis could be chosen to coincide with one of the edges of the acceptance angle and its focus placed at one of the edges of the associated secondary mirror, and also the ellipses can have their focus coinciding with the edges of the cell and of the associated primary mirrors.

An example of a three-dimensional (3D) device is rotationally symmetric, as shown in FIG. 4, so the segments of primary and secondary form rings or annulus structures. Because the Kohler integration is performed in the meridian cross-section, no uniformity is gained in the saggital direction. This means that if the acceptance angle is 3 times the solar disk, the local concentration is only 3 times the average. Therefore, for a 500 suns average concentration, the maximum local concentration on the cell is 1,500 (which is acceptable).

Regarding the local concentration produced on the secondary mirror, when the sun is centered on axis, the irradiance pattern on each segment annulus of the secondary mirror is a thin ring centered on the segment with about 100-150 suns concentration, which is also acceptable for the mirror durability.

If the sun is off-center, but still within the design acceptance angle, the irradiance thin ring on each segment annulus of the secondary is displaced; but it is still inside the segment. In the meridian cross-section, the sun images are thus displaced as shown in FIG. 5. The maximum irradiance levels on the secondary and on the cell remain unchanged.

Dispersion due to the variation of the refractive index of the dielectric material (i.e. glass or acrylic) used significantly limits the solar flux concentration with reasonable acceptance angle (>15 mrad half angle) by a well-designed flat Fresnel lens to ≈150 suns. The angular dispersion due to refraction is:

$$\frac{δθ}{tan θ} = - \frac{δ n}{n} \qquad ( 1 )$$

where n is the relative refractive index at the interface and θ is the refracted angle.

For the concentrator shown in FIG. 3, there are two refractive surfaces: the surface defining the entry aperture 30 and the exit surface 36. In the first refractive surface, if the refractive entrance aperture 30 is flat, the incidence angle is limited to the acceptance angle and equation (1) states (approximating the tangent function by its argument) that relative dispersion of the refraction angle is equal (in absolute value) to relative dispersion of the refractive index, which is below 1% in optical dielectrics. In the second refractive surface, the effect is even smaller since the angular acceptance at that surface is very wide (close to ±90°) and since the dispersion of the relative refractive index δn is much smaller (assuming a limited cell illumination angle (up to about ±45°) since the concentrator dielectric material and the cell encapsulant have a more close variation with wavelength than that of the dielectric and air of the first refraction).

Therefore, the dielectric optical system in FIG. 3 is for practical purposes achromatic. In fact, Equation (1) indicates some flexibility in design. For instance, the dielectric/air interface (the entrance aperture 30) does not have to be strictly normal to the beam. A modest inclination is allowable, just as long as chromatic effects, as determined by Equation (1) are kept reasonably bounded. If the entrance surface is not flat, the rays should be traced in the design. For instance, if the segments of the primary mirror element 31 are parabolas when the entrance surface is flat, when it is non-flat, its shape should be calculated to enable the impinging parallel rays, after the refraction on the non-flat aperture, to be focused on the associated secondary. This calculation is called generalized Cartesian Oval, which in general solves the inverse problem of calculating the optical surface (reflective or refractive) that couples the rays normal to two given wavefronts. The same considerations apply to the change of the exit surface from flat. A hemispherical shape, for instance, could also be used.

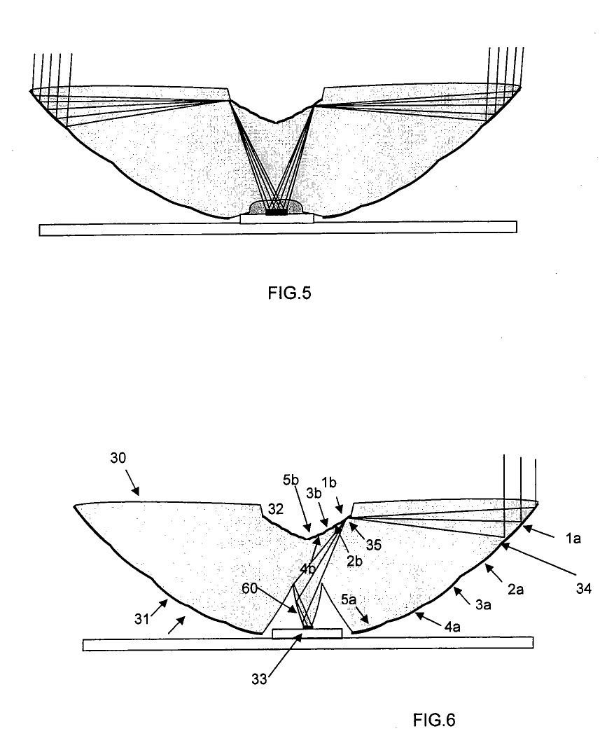

In cases where an increase in concentration or acceptance angle is desired, it is desirable to add a final stage non-imaging concentrator as shown in FIG. 6. This concentrator 60 could be a θ₁/θ₂ non-imaging concentrator where θ1 is chosen to match the numerical aperture (NA₁) at the exit of the two mirror system and where sin θ₁=NA₁/n. The θ₂ is chosen to satisfy a subsidiary condition, such as maintaining total internal reflection (TIR) on the non-imaging concentrator sides or limiting angles of irradiance onto a multi-junction cell. The concentration or flux boost of the terminal stage approaches the fundamental limit of (sin θ₂/sin θ₁)². The overall concentration can approach the etendue limit of (n/sin θ₀)² where sin θ₀=n sin θ₁. In alternative embodiments, the non-imaging concentrator can be a known tailored non-imaging concentrator or a flow line concentrator.

The planar all-dielectric optical system presented here embodies inexpensive high-performance forms that are capable of (a) concentrating the solar radiation with acceptable non-uniform irradiance levels, (b) incurring negligible chromatic aberration even at ultra-high concentration, (c) passive cooling of the cell, (d) accommodating liberal optical tolerances, (e) mass production with existing glass and polymeric molding techniques, and (f) high compactness.

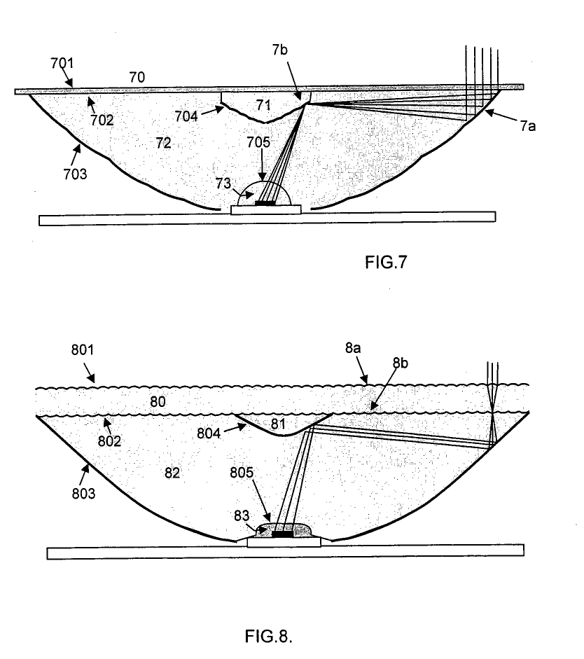

FIG. 7 illustrates a two-mirror Kohler radial homogenizer optical system that may be composed of volumes 70, 71, 72 and 73 of different refractive indices. If volume 72 is air and volumes 70 and 71 are the same dielectric material (so interface 702 does not exist), the device in FIG. 7 reduces to that in FIG. 3. The optical design of the device in FIG. 7 is done in substantially the same way as described for the design of FIG. 3.

Another embodiment considers that volume 71 is air, in which the optical losses due to absorption in that medium are eliminated. In this case, a flat cover 70 prevents dust from accumulation in the system and protects mirror elements from the external environment. If medium 73 is also air, the cell is not encapsulated, which increases the system optical efficiency since the Fresnel reflection on the interface 705 is eliminated. However, to prevent cell degradation by moisture, it is desirable to encapsulate the cell with a dielectric dense medium 73 such as silicone rubber. The prescribed surface 705 of the encapsulating dielectric material will be considered in the design as a prescribed surface through which the rays are traced. Additional surfaces may be included as desired in the system, and the application of the same design procedure of the invention is straightforward for one of skill in the art. For example, the encapsulating lens medium 73 can be made of glass or transparent plastic, and the cell coupled to it with a gel or a silicon rubber. In this case, an additional interface (without a specific optical function) will appear.

Instead of establishing a design of the two mirrors, any other two surfaces of the five surfaces 701, 702, 703, 704 and 705 in FIG. 7 could be designed. Therefore, nine alternative families of devices are illustrated in FIG. 8 to FIG. 16. One skilled in the art will realize that other like configurations can be established using combinations and variations by employing the principals of the invention. For all these cases, the design can be performed in 4 steps according to one aspect:
(1) Prescribe three of the five surfaces,
(2) Calculate the remaining two surfaces in 2D to make the coupling of two parallel input wavefronts defined by the acceptance angle into the two spherical exit wavefronts defined by the target edges. Alternatively, the target and acceptance angle can be scaled down to converge to zero, and then the resulting two surfaces will be aplanatic (i.e., stigmatic and fulfilling the Abbe sine condition). If the calculated surfaces are not manufacturable, a new selection of the three prescribed surfaces in step (1) is performed,
(3) Select two of the five surfaces,
(4) Recalculate the two selected surfaces in (3) containing the Kohler integrator segments as disclosed above, ray tracing through the prescribed or precalculated surfaces.

FIG. 8 illustrates a Kohler homogenizer optical system that includes volumes 80, 81, 82 and 83 of different refractive indices. The Kohler homogenization is done between the two surfaces 801 and 802 of the front top dielectric cover 80. In one embodiment, the medium 82 is air and the lenses in cover 80 are top-down symmetric. The Kohler homogenization can be only in the radial direction. Alternatively, the Kohler homogenization can be done in both the radial and saggital directions using with rotational symmetric lens units in the lens array displaced either in a rectangular or hexagonal pattern. This embodiment would increase further the illumination homogeneity of the lens.

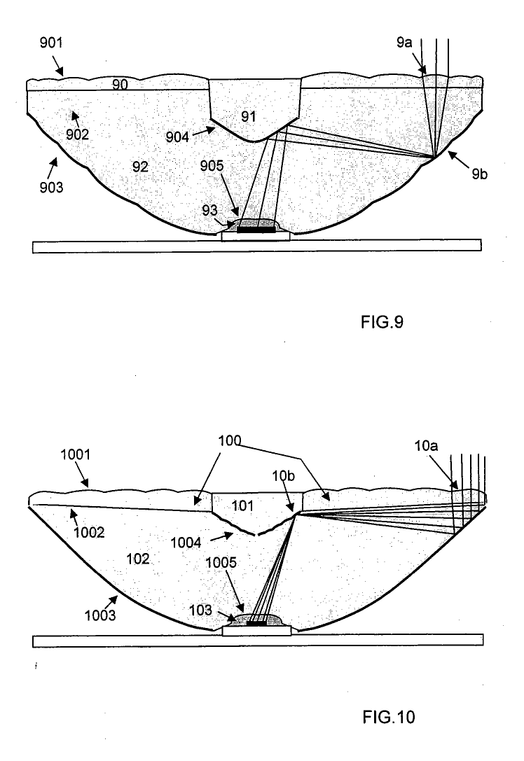

FIG. 9 illustrates a Kohler radial homogenizer optical system that includes volumes 90, 91, 92 and 93 of different refractive indices. Kohler radial homogenization is done between the entry surface 901 and the primary mirror 903. In this case, the focal length and pitch of the lens and mirror segment decrease from the optical axis to the rim, due to the progressively smaller separation of the Kohler integrator pairs.

FIG. 10 illustrates a Kohler radial homogenizer optical system that includes volumes 100, 101, 102 and 103 of different refractive indices; the Kohler radial homogenization is done between the entry surface 1001 and the secondary mirror 1004. In one embodiment, material 101 is air and dielectric material materials 100 and 102 are equal (so interface 1002 does not exist), so that the optical system can be manufactured as a single piece.

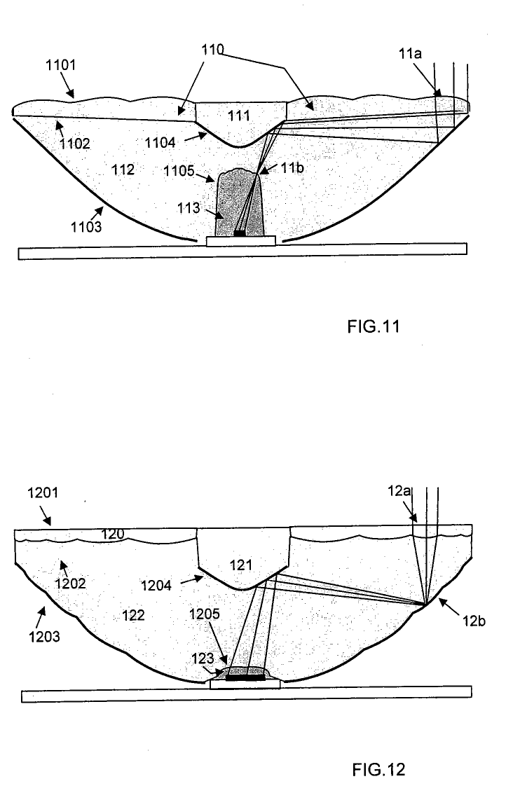

FIG. 11 illustrates a Kohler radial homogenizer optical system that includes volumes 110, 111, 112 and 113 of different refractive indices. The Kohler radial homogenization is done between the entry surface 1101 and the exit surface 1105. In one embodiment, where the material 112 is air, the lens segments of exit surface 1105 are concave. In another embodiment, where the material 112 is a dielectric and volume 113 is air, the lens segments of exit surface 1105 are convex.

FIG. 12 illustrates a Kohler radial homogenizer optical system that includes volumes 120, 121, 122 and 123 of different refractive indices; the Kohler radial homogenization is done between the inner surface 1202 of the top cover and the primary mirror 1203. Also in this case, the focal length and pitch of the lens and mirror segment will decrease from the optical axis to the rim, due to the progressively smaller separation of the Kohler integrator pairs (i.e., pair-wise correlated primary and secondary mirror segments).

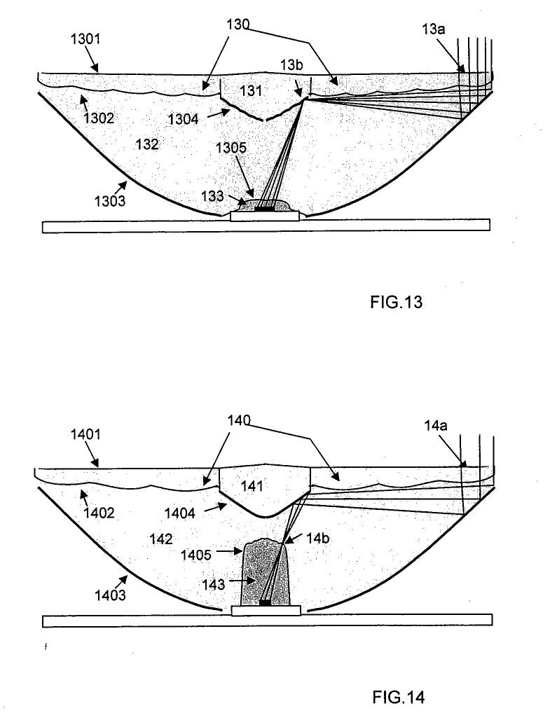

FIG. 13 illustrates a Kohler radial homogenizer optical system that includes volumes 130, 131, 132 and 133 of different refractive indices; the Kohler radial homogenization is done between the inner surface of the top cover 1302 and the secondary mirror 1304. In one embodiment, material 1301 is air and dielectric material materials 1300 and 1302 are equal (so interface 1002 does not exist). In this embodiment, the optical system can advantageously be manufactured as a single piece.

FIG. 14 illustrates a Kohler radial homogenizer optical system that includes volumes 140, 141, 142 and 143 of different refractive indices; the Kohler radial homogenization is done between the inner surface of the top cover 1402 and the exit surface 1405. In one embodiment, material 141 is air and dielectric material materials 140 and 142 are equal (so interface 1402 does not exist). In this embodiment, the optical system can advantageously be manufactured as a single piece. In one embodiment, where the material 112 is air, the lens segments of exit surface 1405 are concave. In another embodiment, where the material 142 is a dielectric and volume 143 is air, the lens segments of exit surface 1405 are convex.

The use of the inner surface instead of outer surface of the cover (for instance, surface 1202 in FIG. 12 instead of surface 901 in FIG. 9) to allocate the Kohler integrator segments is beneficial in cases where the system is used outdoors (as it is usually the case in photovoltaic applications), because the slope discontinuities between segments in the top surface will tend to accumulate dust and thus will need a higher cleaning maintenance.

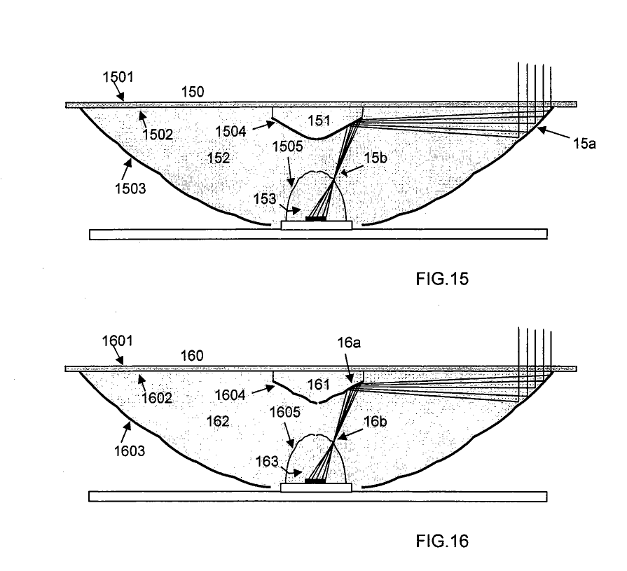

FIG. 15 illustrates a Kohler radial homogenizer optical system that includes volumes 150, 151, 152 and 153 of different refractive indices; the Kohler radial homogenization is done between the primary mirror 1503 and the exit surface 1505. In one embodiment, where the material 152 is air, the lens segments of exit surface 1505 are concave. In another embodiment, where the material 152 is a dielectric and 153 is air, the lens segments of exit surface 1505 are convex.

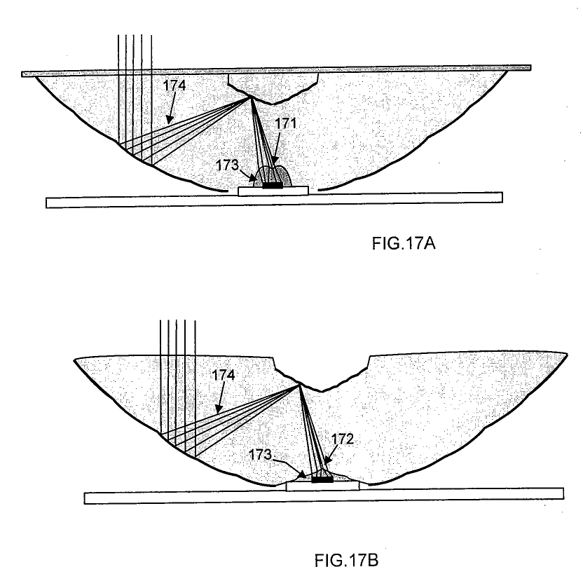

FIG. 16 illustrates a Kohler radial homogenizer optical system that includes volumes 160, 161, 162 and 163 of different refractive indices; the Kohler radial homogenization is done between the secondary mirror 1604 and the exit surface 1605. In one embodiment, where the material 162 is air, the lens segments of exit surface 1605 are concave. In another embodiment, where the material 162 is a dielectric and 163 is air, the lens segments of exit surface 1605 are convex.

When the exit surface is to be selected, it is possible to shape it to improve the uniformity provided by the Kohler homogenizing device when the sun is on-axis, provided that there is a sufficient refractive index difference at both sides of the exit surface. FIGS. 17A and 17B illustrate the uniformity improvement of the exit surface profile by having a concavity 171 or a convexity 172 at the center when the cell side 173 has a higher or lower refractive index, respectively. This profiles cause the rays 174 going to the cell center to deflect when closer to the cell rim.

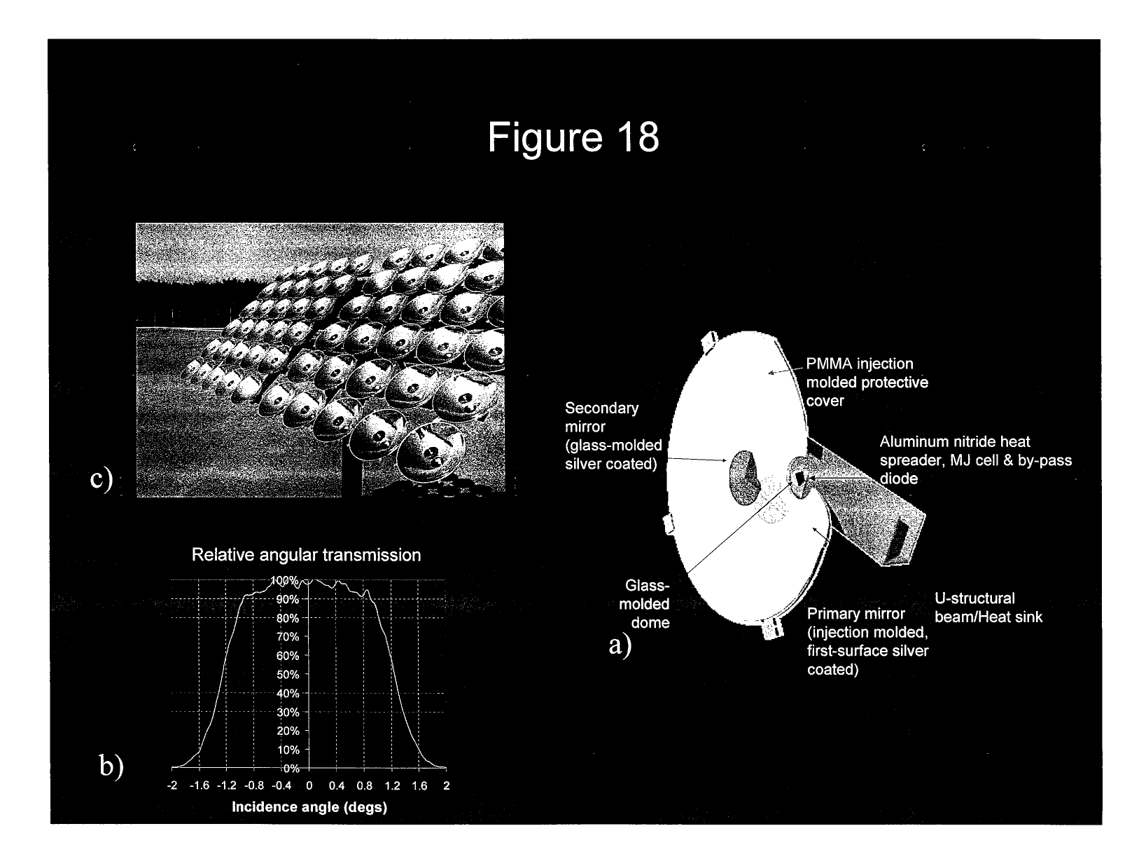

According to one embodiment, a cover made of, for example, glass or PMMA or other suitable material, is positioned to cover and protect the optical elements from the environment, e.g., dust or debris. FIG. 18a illustrates an embodiment including a cover. It will be appreciated that any of the various embodiments discussed herein could benefit from the use of a cover, especially where the internal volume is air.

According to one embodiment, a heat sink is provided on which to mount one or more optical systems. For example, FIG. 18a illustrates a perspective view of a specific optical system having segmented primary and secondary mirror segments as described in the various embodiments above. The specific system shown includes a primary segmented mirror element with silver coated reflecting surfaces and a secondary segmented mirror element with silver coated reflective surfaces. A glass molded dome covers a multi-junction solar cell. As shown, the optical system is mounted or attached to a heat sink. The heat sink as shown is a U-beam structure or comb structure as is well known, however other structures may be used as desired. The heat sink may also provide a platform on which to mount multiple systems. The target cell may be attached directly to the heat sink, or a heat spreader (e.g., Aluminum Nitride) may be provided to couple the heat sink with the target and enhance heat dissipation from the cell to the heat sink.

In certain aspects, a tracking system is provided to reposition the system(s) as needed to track the motion of the sun and maintain the light impinging on the system within a desirable acceptance angle. FIG. 18b shows an example of relative angular transmission as a function of incidence angle for the system of FIG. 18a. FIG. 18c illustrates a plurality of systems mounted on multiple heat sinks. A tracking system coupled to servos and motors allows the array of optical systems shown in FIG. 18c to track the motion of the sun.

While the invention has been described by way of example and in terms of the specific embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An optical device, comprising:
an aplanatic optical imaging system including:
a) a segmented primary reflective element defining an entrance aperture and having a plurality of aspherical primary reflective segments; and
b) a segmented secondary reflective element having a plurality of aspherical secondary reflective segments,
wherein primary and secondary reflective segments are pair-wise correlated so that a primary reflective segment images a field of view onto a corresponding secondary reflective segment, and wherein the secondary reflective segment images the corresponding primary segment onto an exit aperture; and
a target element positioned proximal to a vertex of the primary reflective element.

2. The device of claim 1, wherein the exit aperture is substantially contiguous with the vertex of the primary mirror element.

3. The device of claim 1, wherein the target element comprises a solar cell.

4. The device of claim 1, further comprising a cover positioned proximal to the entrance aperture.

5. The device of claim 1, wherein the plurality of primary and secondary reflective segments are radially symmetric with respect to a central axis.

6. The device of claim 1, wherein one of the secondary reflective segments is coplanar with the entrance aperture.

7. The device of claim 1, wherein the space between the primary and secondary reflective elements comprises air.

8. The device of claim 1, wherein the space between the primary and secondary reflective elements comprises a dielectric material with an index of refraction, n.

9. The device of claim 8, wherein n is in a range from about 1.3 to about 1.5.

10. The device of claim 1, further comprising a non-imaging concentrator having an entrance aperture disposed proximal to the exit aperture.

11. The device of claim 10, wherein the non-imaging concentrator is one of a θ₁/θ₂ concentrator, a tailored non-imaging concentrator or a flow line concentrator.

12. The device of claim 10, wherein the non-imaging concentrator comprises a first dielectric material having an index of refraction different from the material defining an interior of the aplanatic optical imaging system.

13. An optical device, comprising:
an aplanatic optical imaging system including:
a) a segmented primary reflective element defining an entrance aperture and having a plurality of primary reflective segments; and
b) a segmented secondary reflective element having a plurality of secondary reflective segments, and
a target element positioned proximal to an exit aperture,
wherein primary and secondary reflective segments are pair-wise correlated so that light impinging on a primary reflective segment is focused onto a corresponding secondary reflective segment, and wherein the secondary reflective segment images the corresponding primary segment onto the exit aperture such that the target element is substantially uniformly illuminated.

14. The device of claim 13, wherein the primary reflective segments and the secondary reflective segments are aspherical.

15. The device of claim 13, wherein the target element includes a solar cell.

16. The device of claim 13, further comprising a non-imaging concentrator having an entrance aperture disposed proximal to the exit aperture.

17. The device of claim 13, wherein the exit aperture is proximal to the vertex of the primary reflective element.

18. A method of concentrating light onto a solar cell, the method comprising:
positioning an aplanatic optical imaging device to receive incident light from a light source, the device including a segmented primary reflective element having a plurality of primary reflective segments, and a segmented secondary reflective element having a plurality of corresponding secondary reflective segments,
reflecting incident light by the primary mirror segment s onto corresponding secondary mirror segments; and
reflecting the reflected light by the secondary mirror segments onto a target cell, wherein the target cell is substantially uniformly illuminated by the incident light.

19. The method of claim 18, wherein the device further includes a non-imaging concentrator position proximal to the target cell, and wherein the method further includes concentrating the incident light reflected by the secondary mirror segments onto the target cell.

20. The method of claim 18, wherein the light source is the sun, and wherein the method further includes repositioning the device so as to track the motion of the sun such that incident light from the sun is received within an acceptance angle of the device.

21. The method of claim 13, wherein the primary reflective segments and the secondary reflective segments are aspherical.
